(19) United States
(12) Patent Application Publication
(10) Pub. No.: US 2015/0195919 A1
(43) Pub. Date: Jul. 9, 2015

(54) Intelligent Power Module Process

(71) Applicant: Chung Hsing TZU, Taipei (TW)

(72) Inventor: Chung Hsing TZU, Taipei (TW)

(21) Appl. No.: 14/147,609

(22) Filed: Jan. 6, 2014

(51) Int. Cl. H05K 3/34; H01L 21/48; H05K 3/38

(52) U.S. Cl. CPC H05K 3/34; H05K 3/38; H01L 21/4821

(57) ABSTRACT

The present invention is an improved packaging process of Intelligent Motion control Platform (IMP), which regards to the IMP improved process to change the manufacturing, assembling, and packaging process of printed circuit board (PCB) and Electromagnetic Compatibility (EMC). It is an improved manufacturing process to prevent from detecting the defects after IMP finishes packaging. After an IC chip is mounted to the PCB and then they are baked, it is tested first to be sure the IC chip and PCB are electrically connected, and then they are connected the EMS to be packaged together. By adding the above step, the packaged IMP can be sure to be operatable. Although there is an extra step added, the packaged IMP is promised to function. It can reach the goals of the present invention of increase the yield, decrease the number of defected products, and lower the cost.

The present invention relates to the improved manufacturing process of Intelligent Motion control Platform (IMP), especially to the improved Printed Circuit Board manufacturing process of IMP to avoid the risk that the electrical communication of the PCB is not functioned after the PCB and EMC are packaged together so that the IMP module is a defected product. Therefore, the packaged IMP can be sure to be operatable, and it can reach the goals of the present invention of increase the yield, decrease the number of defected products, and lower the cost.

### BACKGROUND OF THE INVENTION

The conventional IMP packaging process is shown in FIG. 1. The PCB and EMC manufacturing processes proceed concurrently, and then they are packaged together. The main process comprises the following g steps:

(A) for PCB:

Step 1: soldering the passive components, such as resisters and capacitors, to the PCB;

Step 2: delivering the above PCB with the passive components into the soldering oven for melting first and solidifying later;

Step 3: removing the PCB out of the oven and then mounting an IC chip to the PCB;

Step 4: baking the PCB with the IC chip in the baking oven;

Step 5: wiring to the IC chip for electrical connection.

(B) for EMC:

Step 1: disposing the FRD and IGBT in the lead frame;

Step 2: melting first and solidifying later in the soldering oven;

Step 3: wiring to the FRD and IGBT respectively.

(C) packaging:

Step 1: connecting the finished PCB and EMC by wiring to connect the IGBT and PCB to form the IMP;

Step 2: packaging the IMP;

Step 3: stamping on the packaged IMP;

Step 4: tin-electroplating for the leads of the IMP;

Step 5: baking the packaged IMP in the baking oven for shaping;

Step 6: removing the IMP out of the baking oven to cut for singulation;

Step 7: testing the IMP for electrical connection.

In the above process, especially regarding to the PCB manufacturing process, there is no test following the wiring step after the IC chip is mounted to the PCB. It is not detected if the IC chip mounted to the PCB is a defect product. It is not sure the electrical connection can function after the IC chip wiring. There is only one test after the PCB and EMC are packaged together. Under the only one test, if a defect IC chip or non-working electrical connection is detected, the whole packaged IMP module has to be abandoned. Therefore, the yield decreases and the material cost increases. To resolve the above problems, an improved packaging process is provided.

### SUMMARY OF THE INVENTION

The present invention relates to the improved manufacturing process of Intelligent Motion control Platform (IMP). Mainly regarding to the PCB manufacturing process, there is s test following the baking step after the IC chip is mounted to the PCB. After verifying the IC chip and the PCB are electrically connected, they are packaged with EMC to avoid the risk that the electrical communication of the PCB is not functioned after the PCB and EMC are packaged together so that the IMP module is a defected product. Therefore, the packaged IMP can be sure to be operatable, and it can reach the goals of the present invention of increase the yield, decrease the number of defected products, and lower the cost.

### BRIEF DESCRIPTION OF THE DRAWINGS

FIG. 1 is the flowchart of the conventional IMP packaging process.

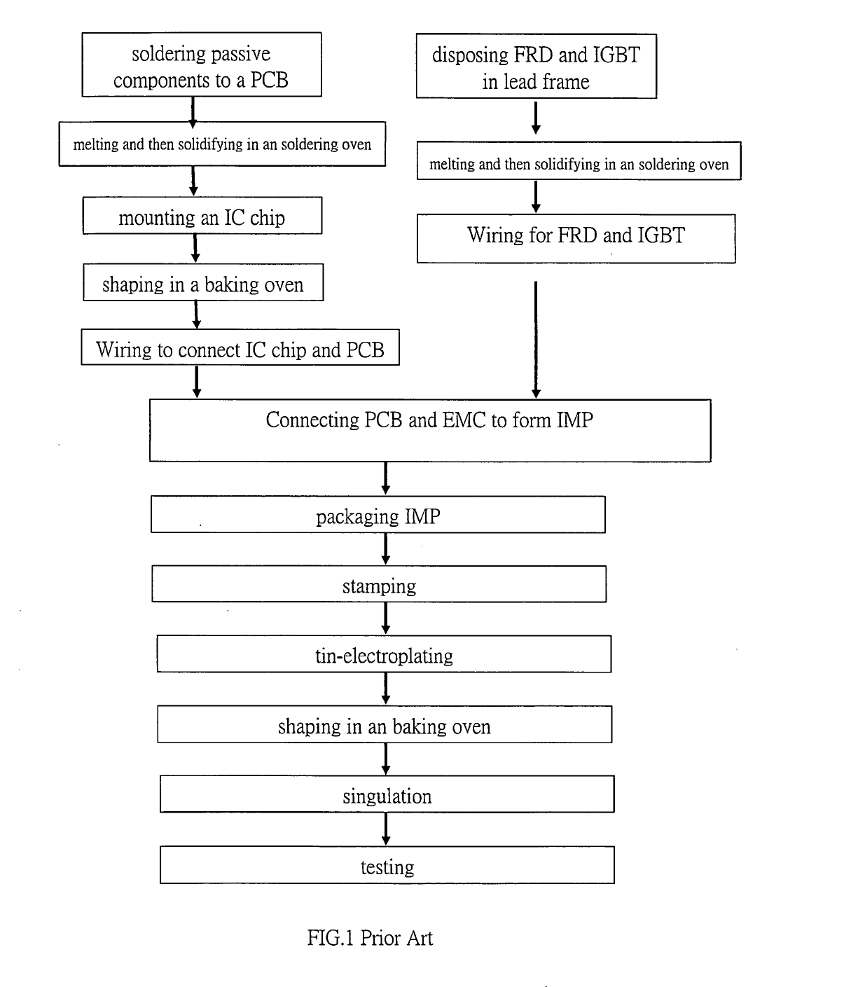

FIG. 2 is the flowchart of the improved IMP packaging process according to the present invention

FIG. 3 is the cross-section of the lateral view of the packaged IMP according the present invention.

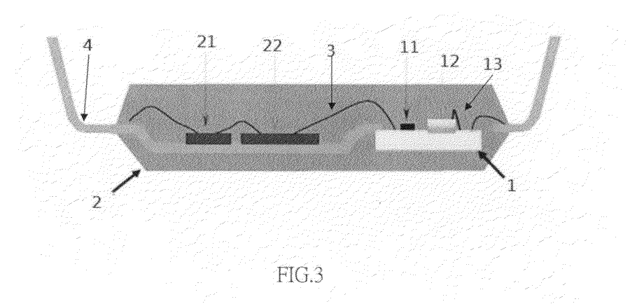

### DETAILED DESCRIPTION OF THE PREFERRED EMBODIMENT

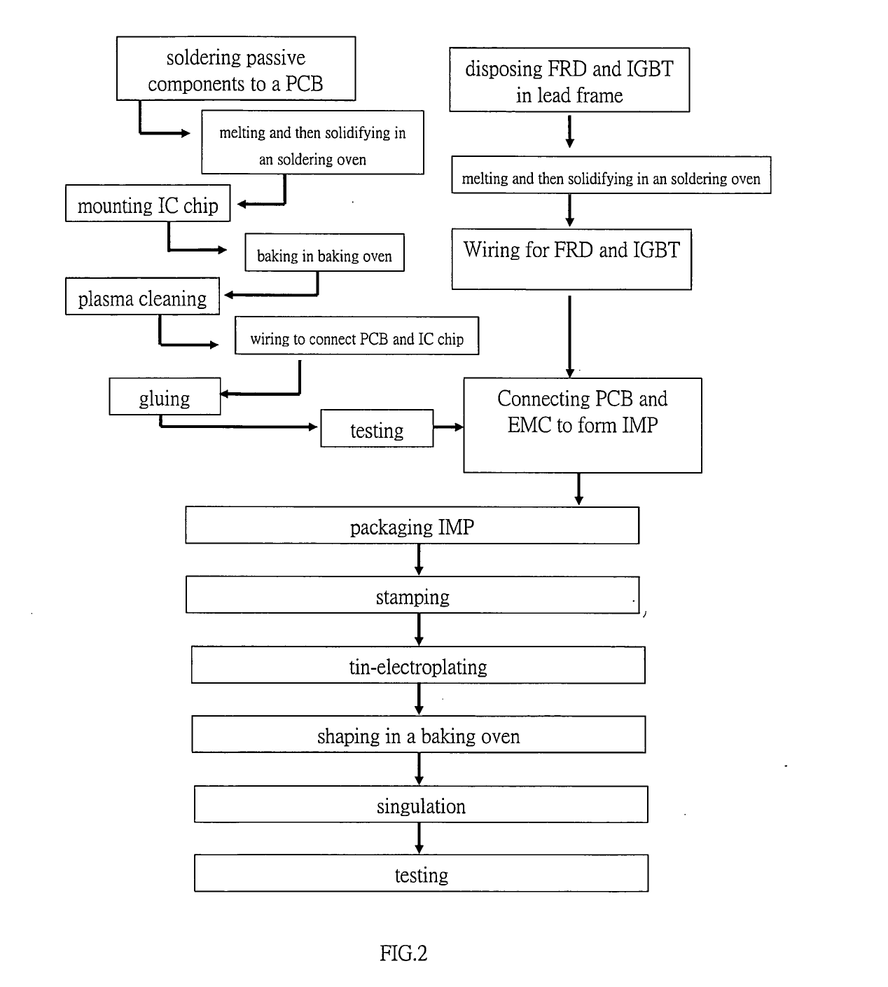

Referring to FIG. 2, it is an improvement for IMP manufacturing and packaging. IMP comprises two parts, PCB and EMC. They can be manufactured separately, and then packaged together. The improved process is as the followings:

(A) for PCB 1:

Step 1: soldering passive components 11, such as capacitors or resistors, to the PCB 1;

Step 2: delivering the PCB 1 soldered with the passive components 11 into the soldering oven to melt first and solidify later;

Step 3: removing the solidified PCB 1 out of the oven and then mounting an IC chip 12 to the PCB 1;

Step 4: baking the PCB 1 mounted with the IC chip 12 in the baking oven;

Step 5: removing the PCB 1 mounted with the IC chip 12 out of the baking oven, and then proceeding with plasma-cleaning;

Step 6: wiring to the IC chip 12 for electrical connection between the IC chip 12 and the PCB 1;

Step 7: gluing to strengthen and secure the wiring portions;

Step 8: electrically testing for the IC chip 12.

(B) for EMC:

Step 1: disposing FRD 21 and IGBT 22 in the lead frame 4;

Step 2: delivering the lead frame 4 disposed with the FRD 21 and IGBT 22 into the soldering oven to melt first and solidify later;

Step 3: wiring to the FRD 21 and IGBT 22 respectively.

(C) packaging:

Step 1: connecting the finished PCB 1 and finished EMC 2 by wiring to form an IMP;

Step 2: packaging the IMP;

Step 3: stamping on the packaged IMP;

Step 4: tin-electroplating the IMP;

Step 5: baking the packaged IMP in the baking oven to finalize the form;

Step 6: removing the IMP out of the baking oven to cut for singulation;

Step 7: electrically testing the IMP.

In the present invention, the gluing step for strengthening and securing and the testing step are followed by the wiring step for mounting the IC chip to the PCB. Therefore, after the EMC is connected to form the IMP, the electrical connection of the PCB and the EMC can be verified to be working. It can avoid the problem that the electrical connection of the PCB is detected to be not working after the packaging is finished. The present invention not only can decrease the defect rate to increase the yield, but also can decrease the waste of the material caused by the defects. In the meantime, the gluing step can increase the electrical communication.

What is claimed is:

1. An improved packaging process for Intelligent Motion control Platform, comprising:
step 1 for soldering a plurality of passive component to a printed circuit board (PCB);
step 2 for delivering the PCB to an soldering oven to melt first and solidify later;
step 3 for removing the PCB out of the soldering oven and then mounting an IC chip to the PCB;
step 4 for baking the PCB in a baking oven;
step 5 for removing the PCB out of the baking oven and then proceeding with plasma-cleaning;
step 6 for wiring to electrically connect an IC chip and the PCB;
step 7 for gluing to strengthen and secure the IC chip after wiring;
step 8 for electrically testing the IC chip;
step 9 for disposing an FRD and an IGBT in an lead frame;
step 10 for delivering the lead frame into the soldering oven to melt first and solidify later;
step 11 for wiring to the FRD and the IGBT respectively;
step 12 for connecting the PCB and an EMC by wiring to form an IMP;
step 13 for packaging the IMP;
step 14 for stamping on the IMP;
step 15 for tin-electroplating a plurality of leads of the IMP;
step 16 for baking the IMP in the baking oven for shaping;
step 17 for removing the IMP out of the baking oven to cut for singulation; and
step 18 for electrical testing the IMP.

2. The method as claimed in claim 1, wherein steps relating to PCB and the steps relating to EMC can proceed separately and concurrently.
